(19) United States
(12) Patent Application Publication
(10) Pub. No.: US 2023/0197155 A1
(43) Pub. Date: Jun. 22, 2023

(54) TERNARY CONTENT ADDRESSABLE MEMORY AND OPERATION METHOD THEREOF

(71) Applicant: MACRONIX INTERNATIONAL CO., LTD., Hsinchu (TW)

(72) Inventors: Po-Hao TSENG, Taichung City (TW); Feng-Min LEE, Hsinchu City (TW); Yu-Hsuan LIN, Taichung City (TW)

(21) Appl. No.: 17/558,673

(22) Filed: Dec. 22, 2021

(51) Int. Cl. G11C 15/04

(52) U.S. Cl. CPC G11C 15/046

(57) ABSTRACT

Disclosed are TCAM device and operation method thereof. The operation method of the TCAM device comprises: applying a select voltage on one of a plurality of first signal lines, and applying an pass voltage on the rest of the first signal lines, wherein the TCAM device comprises an IMS array, the IMS array comprises a plurality of memory units, the memory units are arranged as a plurality of rows and a plurality of columns, a plurality of control terminal of each row of the memory units are coupled to the first driving circuit via a first signal line, each column of the memory units are serially connected to form a memory unit string, each of the memory unit string is coupled to the second driving circuit via a second signal line; and applying a plurality of searching voltage corresponding to a target data to the second signal lines.

### BACKGROUND OF THE INVENTION

### Field of the Invention

The invention relates to a ternary content addressable memory and an operation method thereof.

### Description of the Related Art

Traditional operation method for NAND-type ternary content addressable memory (TCAM) is to use word lines as search lines. In this way, is the allowable length of data is limited by the quantity of the word lines. In the present processing technique of TCAM, the quantity of the word lines generally much less than the bit lines. This may cause the conventional operation method for TCAM difficult to deal with the increasing of data length. These data could be image with high resolution and floating point value with high precision.

### SUMMARY OF THE INVENTION

An embodiment of the present invention discloses a ternary content addressable memory (TCAM) device. The TCAM device comprises a first driving circuit, a second driving circuit, a sensing circuit and an in-memory searching (IMS) array. The IMS array comprises a plurality of memory units. The plurality of memory units are arranged as a plurality of rows and a plurality of columns. A plurality of control terminal of each row of the memory units are coupled to the first driving circuit via a first signal line. Each column of the memory units are serially connected to form a memory unit string. Each of the memory unit string is coupled to the second driving circuit via a second signal line, and is coupled to the sensing circuit via a third signal line. For each row of the memory units, every two adjacent memory units are configured as a memory cell, to store one of a first value, a second value and don′ care.

Another embodiment of the present invention discloses an operation method of ternary content addressable (TCAM) device, comprising: by a first driving circuit of a TCAM device, applying a select voltage on one of a plurality of first signal lines, and applying an pass voltage on the rest of the first signal lines, wherein the TCAM device comprises an in-memory searching (IMS) array, the IMS array comprises a plurality of memory units, the plurality of memory units are arranged as a plurality of rows and a plurality of columns, a plurality of control terminal of each row of the memory units are coupled to the first driving circuit via a first signal line, each column of the memory units are serially connected to form a memory unit string, each of the memory unit string is coupled to the second driving circuit via a second signal line; and by the second driving circuit, applying a plurality of searching voltage corresponding to a target data to the second signal lines.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a block diagram of ternary content addressable memory device according to an embodiment of the present invention.

FIG. 2 shows a block diagram of memory cell according to an embodiment of the present invention.

FIG. 3-5 show schematic diagrams of the operation of memory cell according to an embodiment of the present invention.

FIG. 6 shows a flowchart of operation method according to an embodiment of the present invention.

FIGS. 7-10 show block diagrams of sensing circuit according to embodiments of the present invention.

FIG. 11 shows a schematic diagram of the first searching voltage according to an embodiment of the present invention.

### DETAILED DESCRIPTION OF THE INVENTION

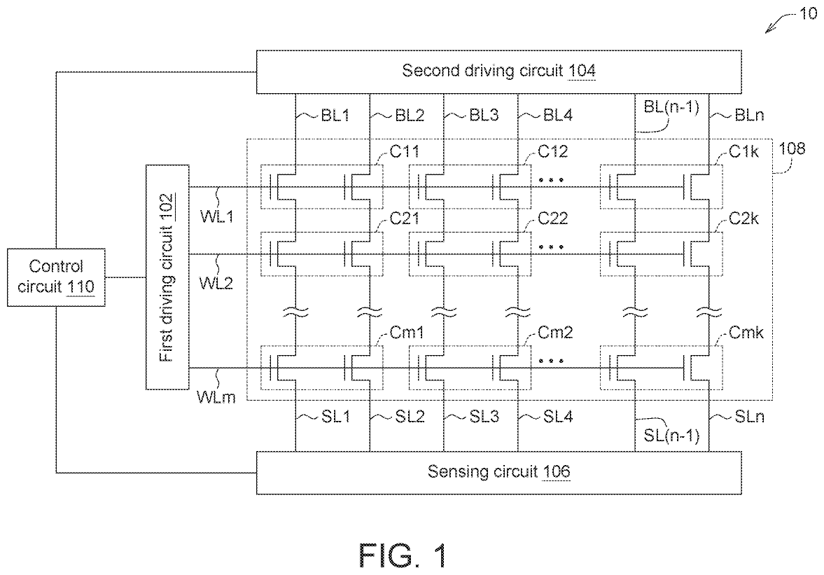

Referring to FIG. 1, FIG. 1 shows a block diagram of ternary content addressable memory (TCAM) device according to an embodiment of the present invention. The TCAM device 10 is a NAND-type memory. The TCAM device 10 includes a first driving circuit 102, a second driving circuit 104, a sensing circuit 106, a in-memory searching (IMS) array 108, a number of first signal lines WL1˜WLm, a number of second signal lines BL1˜BLn, a number of third signal lines SL1˜SLn and a control circuit 110. The IMS array 108 includes a number of memory units. The memory units are arranged as m rows and n columns, wherein m n are positive integers. Preferably, n is an even value. The control terminals of the memory units of the i-th row are coupled to the first driving circuit 102 via the first signal lines WLi. The memory units of the j-th column are serially connected to form a memory unit string, and the memory unit string is coupled to the second driving circuit 104 via the second signal line BLj, and coupled to the sensing circuit 106 via third signal line SLj, wherein l is a positive integer not greater than m, and j is a positive integer not greater than n. In each row of memory units, the two memory units of two adjacent columns are configured as a memory cell. For example, in row 1, the memory units of column 1 and column 2 are configured as the memory cell C11 the memory units of column 3 and column 4 are configured as the memory cell C12, . . . , and in row m, the memory units of column (n−1) and column n are configured as the memory cell Cmk, wherein k is n/2. The structure of the memory units depends on the memory type of the IMS array, wherein the memory type of the IMS array could be floating gate memory, SONGS memory, floating dot memory, ReRAM, FeRAM, phase-chage memory (PCM), conductive-bridging RAM (CBRAM), and so on. The control circuit 110 is coupled to the first driving circuit 102, the second driving circuit 104 and the sensing circuit 106, and configured to control the behavior and the operation of the first driving circuit 102, the second driving circuit 104 and the sensing circuit 106 by using signals. That is, the control circuit 110 is configured to perform the operation method of the present invention.

In an embodiment, the first signal lines are word lines, the second signal lines are bit lines, and the third signal lines are source lines.

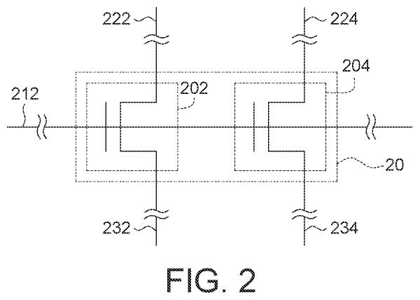

Referring to FIG. 2, FIG. 2 shows a block diagram of memory cell according to an embodiment of the present invention. The memory cell 20 includes memory units 202 and 2204. The control terminals of the memory units 202 and 204 are coupled to the first driving circuit via the same first signal line 212. A first terminal of the memory unit 202 is directly or indirectly coupled to the second driving circuit via the second signal line 222. A second terminal of the memory unit 202 is directly or indirectly coupled to the sensing circuit via the third signal line 232. A first terminal of the memory unit 204 is directly or indirectly coupled to the second driving circuit via the second signal line 224. A second terminal of the memory unit 204 is directly or indirectly coupled to the sensing circuit via the third signal line 234. The memory cell 20 could represent any one of the memory cell C11˜Cmk. By the first driving circuit and the second driving circuit applying suitable bias, the threshold voltage of the memory units 202 and 204 could be programed. The combination of the threshold voltage of the memory units 202 and 204 could be configured to store data representing a first value (e.g., 0), a second value (e.g., 1), don't care (represented by “X”) and invalid data. “Don't care” refers to the data that could be matched whether 0 or 1 is searched. The relationship between the data stored in the memory cell 20 and the threshold voltages is shown in Table 1 and FIG. 3.

TABLE 1

memory unit

| Data | 202 | 204 |
|---|---|---|
| First value | VTH | VTL |
| Second value | VTL | VTH |
| Don't care | VTH | VTH |
| Invalid data | VTL | VTL |

In Table 1 and FIG. 3, VTH represents that the threshold voltage of the memory unit is programmed to a high threshold voltage, VTL represents that the threshold voltage of the memory unit is programmed to a low threshold voltages.

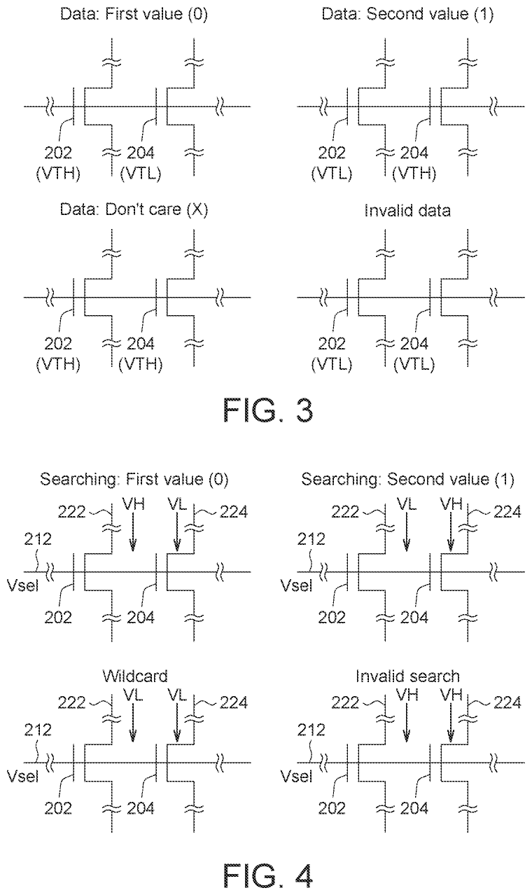

Table 2 and FIG. 4 show the bias applied on the signal lines under the search operation.

TABLE 2

search input

| | First | Second | | Invalid |
|---|---|---|---|---|
| Signal line | value | value | Wildcard | search |
| 222 | VH | VL | VL | VH |
| 224 | VL | VH | VL | VH |
| 212 | Vsel | Vsel | Vsel | Vsel |
| The first signal | Vpas | Vpas | Vpas | Vpas |
| line in addition | | | | |
| to 212 | | | | |

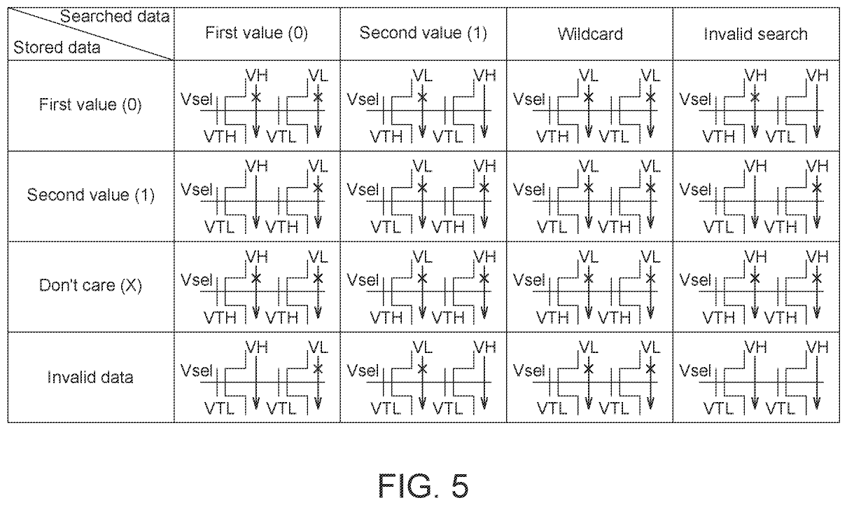

In Table 2 and FIG. 4, VH is a first searching voltage, VL is a second searching voltage, Vsel is a selet voltage, Vpas is an pass voltage. In an embodiment, VTH>VH>VTL>VL. In this embodiment, “matched” refers to there is no current flowing out from the second terminals of the memory units 202 and 204. In practice, Vsel, Vpas, VH and VL could be determined according to Table 3, the probability distribution of VTH/VTL and the characteristics of the memory units, wherein Table 3 shows the relationship between the bias and the status of the memory units 202/204. Table 3 could be read with reference to FIG. 5 for easier understanding. FIG. 5 shows the relationship between the stored data, the searched data and the state of the memory units.

TABLE 3

| Threshold | Bias on first | Bias on second | Status of |
|---|---|---|---|
| voltage | terminal | terminal | memory unit |
| VTH | Vsel | VH | OFF |
| VTH | Vsel | VL | OFF |
| VTH | Vpas | VH | ON |
| VTH | Vpas | VL | ON |
| VTL | Vsel | VH | ON |
| VTL | Vsel | VL | OFF |
| VTL | Vpas | VH | ON |
| VTL | Vpas | VL | ON |

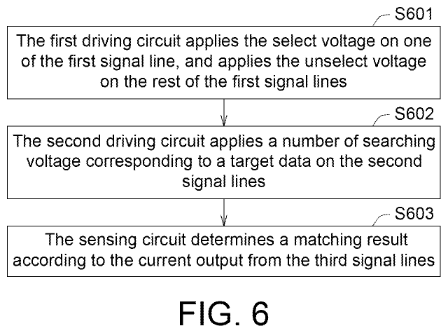

After understanding the operation of respective memory cell, the searching operation of the TCAM device 10 would be illustrated with referring to FIG. 1 and FIG. 6. Noted that the programming operation and the erase operation of the TCAM device 10 could apply any suitable approach in the present art, and may not be described herein.

FIG. 6 shows a flowchart of operation method according to an embodiment of the present invention. The operation method could be performed by the control circuit 110 sending commands and clock signal to the first driving circuit 102, the second driving circuit 104 and the sensing circuit 106.

At step S601, the first driving circuit 102 applies the select voltage Vsel on one of the first signal line WL1˜WLm, and applies the pass voltage Vpas on the rest of the first signal lines. For example, when the first signal line WL1 is to be searched, the first driving circuit 102 applies the select voltage Vsel on the first signal line WL1, and applies the pass voltage Vpas on the rest of the first signal lines WL2˜WLm.

At step S602, the second driving circuit 104 applies a number of searching voltage corresponding to a target data on the second signal lines BL1˜BLn. The searching voltages corresponding to the target data refer to the bias applied on the second signal lines that are determined based on the relationship between the searched value and the bias on the signal lines shown in Table 2 and according to the target data to be searched. For example, it is assumed that the target data to be searched is 01X1. The bias applied on the second signal lines BL1˜BL8 are respectively VH, VL, VL, VH, VL, VL, VL, VH.

At step S603, the sensing circuit 106 determined a matching result according to the current flowing out from the third signal lines SL1˜SLn.

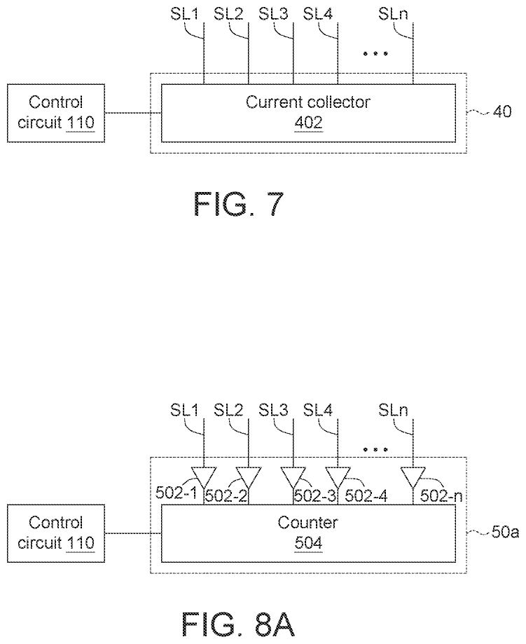

As shown in FIG. 7, in an embodiment, the sensing circuit 40 includes a current collector 402. The current collector 402 is coupled to the third signal lines SL1˜SLn, and configured to collect and add up the current flowing out from the third signal lines SL1˜SLn to obtain a total current. The total current could be used as the matching result to output. When the total current is substantially zero, it represents that the data stored in the memory cells on the selected first signal line perfectly matches the target data. When the total current is not substantially zero, it represents that the data stored in the memory cells on the selected first signal line fails to perfectly match the target data. The larger the total current, the lower the matching degree is.

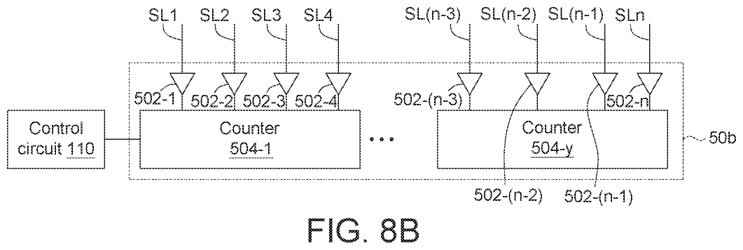

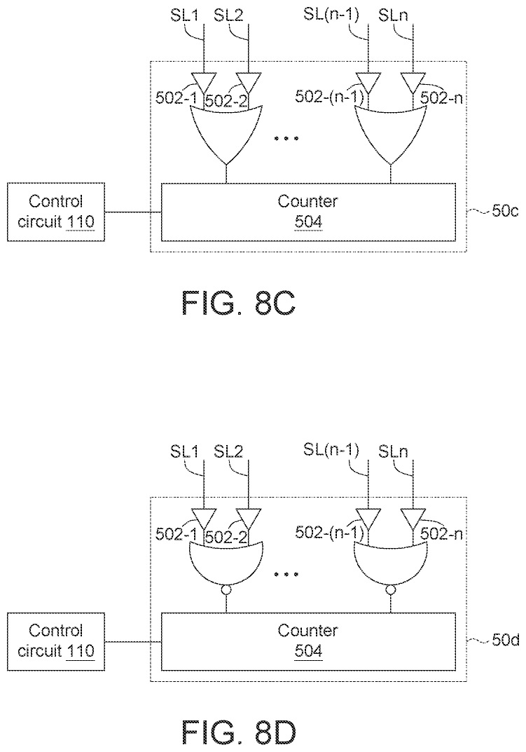

As shown in FIG. 8A, in another embodiment, the sensing circuit 50a includes a number of sensing units 502-1˜502-n and a counter 504. The sensing unit 502-1˜502-n are respectively coupled to the third signal lines SL1˜SLn, and configured to output 0 or 1 according to whether the current flowing out from the coupled third signal line is zero. When the current flowing out from the third signal line coupled to the sensing unit is not zero, the sensing unit outputs 1. When the current flowing out from the third signal line coupled to the sensing unit is zero, the sensing unit outputs 0. The counter 504 is coupled to the sensing units 502-1˜502-n, and configured to add up the 1's output from the sensing units 502-1˜502-n to generate a total value. The total value could be used as the matching result to output. When the total value is zero, it represents that the data stored in the memory cells on the selected first signal line perfectly match the target data. When the total value is not zero, it represents that the data stored in the memory cells on the selected first signal line fails to perfectly match the target data. The larger the total value, the lower the matching degree is.

Referring to FIG. 8B, FIG. 5B shows a block diagram of sensing circuit according to yet another embodiment of the present invention. The difference between the sensing circuit 50b and the sensing circuit 50a is that the sensing units 502-1 of the sensing circuit 50b are coupled to a number of counters 504-1˜504-y. That is, the sensing circuit could employ one counter to calculate the amount of 1 output by all the sensing units, or the sensing circuit could employ a number of counters to group the sensing units and calculate the amount of 1 output by each group of the sensing units.

Refer to FIGS. 80 and 8D. In yet another embodiment, as shown in FIG. 8C, the sensing circuit 50c could further include a number of OR gate 503-1˜503-k. In yet another embodiment, as shown in FIG. 8D, the sensing circuit 50d could further include a number of OR gate 505-1˜505-k. The outputs of the two sensing units corresponding to the same memory cell could be coupled to an OR gate or a NOR gat. For example, the outputs of the sensing units 502-1, 502-2 could be coupled to an OR gate or a NOR gate. According to the output of the OR gate or the NOR gate, it could be determined that whether the data bit stored in the memory cell is matched. In the embodiment of OR gate, the OR gate outputting 0 represents matched, and outputting 1 represents mismatched. In the embodiment of NOR gate, the Nor gate outputting 1 represents matched, and outputting 0 represents mismatched.

In the sensing circuit 40, the matching degree is represented by the total current. Smaller total current represents higher matching degree, and greater total current represents lower matching degree. In the sensing circuit 50a˜50d, the matching degree is represented by the quantity of “1” (i.e., the total value). Smaller total value represents higher matching degree, and greater total value represents lower matching degree. Since the matching results provided by the sensing circuits 40 and 50a-50d could represent the matching degree between the data stored in the memory cells on the selected first signal line and the target data, the present invention could be applied to approximate search. For example, in the embodiment of the sensing circuit 40, a current threshold could be configured. The total current being smaller than the current threshold is defined as matched, and the total current not being smaller than the current threshold is defined as mismatched. In the embodiment of the sensing circuit 50a, a threshold value could be configured. The total value being smaller than the threshold value is defined as matched, and the total value not being smaller than the threshold value is defined as mismatched. In this way, data that meets the condition could be filtered out from the IMS array.

The characteristic that the matching degree is related to the number of 1s/the sum of currents detected by the sensing circuit allows the present invention to be applied to high-resolution image search.

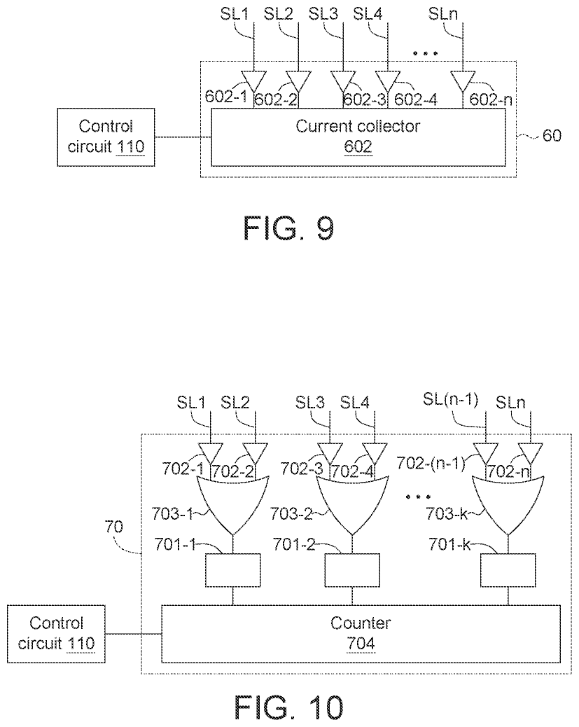

In an embodiment, as shown in FIG. 9, the sensing circuit 60 could further includes a number of current amplifiers 601-1˜601-n. The third signal lines SL1˜SLn are coupled to the current collector 602 via the current amplifiers 601-1˜601-n. The current amplifiers 601-1˜601-n could be configured to have gains which are different or partly the same. The current amplifiers could amplify the current flowing out from the third signal lines and then output the amplified current. It is equivalent to give the current flowing out from the third signal line a weight. In some applications, in a piece of data, the bit that more close to the most significant bit (MSB) has higher importance, and the bit that more close to the least significant bit (LSB) has lower importance, Therefore, giving the current flowing out from the third signal lines different weights could represent the difference in importance of the bits at different position of a piece of data. For example, it is assumed that the memory cells (C11˜Cm1) corresponding to the third signal lines SL1, SL2 are configured to store the MSBs, and the memory cells (C1n˜Cmn) corresponding to the third signal lines SL(n−1), SLn are configured to store the LSBs. The gains G1, G2 of the current amplifiers 601-1, 601-2 could be configured to 3, the gains G3, G4 of the current amplifiers 601-3, 601-4 could be configured to 2, the gains G5˜Gn of the rest current amplifiers 601-5˜601-n could be configured to 1, to represent the memory cells (C11˜Cm1) corresponding to the third signal lines SL1, SL2 storing the most important bit of the stored data. Noted that the gains G1˜Gn of the current amplifiers 601-1˜601-n could be adjusted based on need. It is not limited that the gain corresponding to the MSB must be the greatest one. In an alternative embodiment, the quantity of the current amplifiers could be less than the quantity of the third signal lines, That is, some of the third signal lines could not be coupled to the current collector via the current amplifier.

In another embodiment, as shown in FIG. 10, the sensing circuit 70 could further include a number of gain units 701-1˜701-k and a number of OR gates 703-1˜703-k, the outputs of the sensing units corresponding to the same memory cell are coupled to the two inputs of the same OR gate. The OR gates 703-1˜703-k are coupled to the counter 704 via the gain units 701-1˜701-k. In an embodiment, the gain units 701-1˜701-n could be configured based on need, to cause the gain units 701-1˜701-n to have gains W1˜Wk which are different or partly the same. The gain unit could multiply the output of the sensing unit by the gain of the gain unit and then output the product, to represent the importance of the bit. For example, the gain of W1 of the gain unit 701-1 corresponding to the MSB could be configured to be greater than the gains W2˜Wk of the rest gain units 701-2˜701-k, to represent the importance of the bit. In an alternative embodiment, the quantity of the gain units could be less than the quantity of the OR gates, That is, some of the OR gates could not be coupled to the counter via the gain unit.

The current amplifier and the gain unit belong to a weight means. The weighting means refers to a means for giving respective weight/gain to the current flowing out from at least one of the third signal lines or digital/analog signal derived from the same. That is, the sensing circuit could include a weighting means for giving respective weight/gain to the current flowing out from at least one of the third signal lines or digital/analog signal derived from the same.

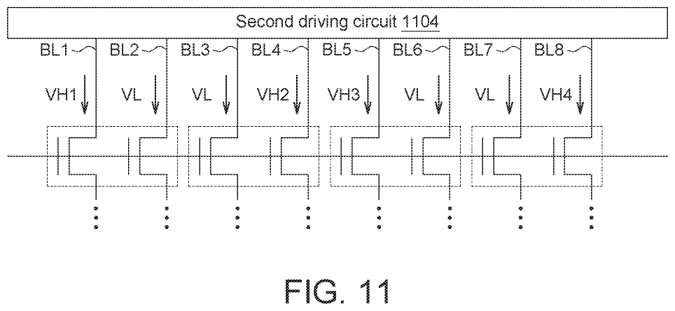

In yet another embodiment, in the embodiment applying the sensing unit 40, the second driving circuit adjusts the first searching voltage VH applied on the second signal lines according to the importance of the bits, to cause the first searching voltage VH applied on different second signal lines to be different of partly the same. For example, the first searching voltage VH applied on the second signal lines corresponding to more importance bit may be greater, and the first searching voltage VH applied on the second signal lines corresponding to less importance bit may be smaller. In an example shown in FIG. 11, the importance of the data bits stored in the memory cells decreases from left to right. The data string to be searched is 0101. The bias applied by the second driving circuit 1104 on the second signal lines BL1˜BL8 are VH1, VL, VL, VH2, VH3, VL, VL and VH4 respectively, wherein VH1>VH2>VH3>VH4 is configured to represent the importance of the data bits. Since one of the memory units of a memory cell would be operated in linear region while the data stored in the memory cell mismatch the searched data, the greater the VH, the greater the current flowing out from third signal line is. Therefore, the effect of representing the difference in importance between the bits could be achieved.

The present invention could further implement searching and storing numerical range. Searching numerical range could be implemented by using wildcard in searching. For example, while 110*** (*represents a bit of wildcard) is searched, 110000˜110111 could be matched, That is, the decimal range of 48˜55 could be searched, Storing numerical range could be implemented by using don't care in storing. For example, while 110XXX (X represents a bit of don't care) is stored, it could be matched while 110000˜110111 are searched. That is, the decimal range of 48˜55 is stored.

The amount of the second signal lines would be a great number, the number of data bits that could be stored on each of the first signal lines may achieve page size, for example, 32 kbits, 64 kbits or 128 kbits. In an application, a piece of data could be stored on one first signal line with a number of copies thereof. For example, it is assumed that the memory cells on a first signal line could store 32 kbits data. While a 8 kbits data is to be stored, the 8 kbits data could be stored in the memory cells on a first signal line with three copies of the 8 kbits data so that the first signal line would store four identical data. For example, the 1st˜8000th memory cells store the 8 kbits data, the 8001th˜16000th memory cells store the first copy of the 8 kbit data, the 16001th˜24000th memory cells store the second copy of the 8 kbit data, and the 24001th˜32000th memory cells store the third copy of the 8 kbit data. In this way, the impact of damaged memory cells on the reliability of stored data could be reduced.

The TCAM device and the operation method of the present invention could allow data with longer length by applying searching voltage on the bit lines. Therefore, the present invention could apply to searching of image with high resolution and float point value with high precision. Moreover, weighting the current flowing out from the source lines according to the importance of the corresponding bit could achieve the effect of representing the importance of the bit on the matching result.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A ternary content addressable memory (TCAM) device, comprising:
a first driving circuit;
a second driving circuit;
a sensing circuit; and
an in-memory searching (IMS) array, comprising a plurality of memory units, the plurality of memory units arranged as a plurality of rows and a plurality of columns, a plurality of control terminal of each row of the memory units coupled to the first driving circuit via a first signal line, each column of the memory units serially connected to form a memory unit string,
wherein each of the memory unit string is coupled to the second driving circuit via a second signal line, and each of the memory unit string is coupled to the sensing circuit via a third signal line,
wherein for each row of the memory units, every two adjacent memory units are configured as a memory cell, to store one of a first value, a second value and don't care.

2. The TCAM device according to claim 1, further comprising a control circuit, coupled to the first driving circuit, the second driving circuit and the sensing circuit, the control circuit configured to perform a search operation, the search operation comprising:
controlling the first driving circuit to apply a select voltage to one of the first signal lines, and apply a pass voltage to the rest of the first signal lines; and
controlling the second driving circuit to apply a number of searching voltages corresponding to a target data to the second signal lines.

3. The TCAM device according to claim 2, wherein the sensing circuit comprises a current collector configured to collect and add up currents flowing out from the third signal lines to obtain a total current, and a result of comparing the total current with a predetermined threshold represents whether data stored in the memory cells, being coupled to the first signal lines which are applied with the select voltage, match the target data.

4. The TCAM device according to claim 2, wherein sensing circuit comprises a plurality of sensing units and a counter, the sensing units are respectively coupled to the third signal lines, and configured to output 0 or 1 according to whether a current flows out form the coupled third signal line, the counter is coupled to the sensing units, and configured to add up the amount of 1 output form the sensing unit to obtain a total value, and a result of comparing the total value with a predetermined threshold represents whether the data stored in the memory cells on the first signal line applied the select voltage matches the target data.

5. The TCAM device according to claim 2, wherein sensing circuit comprises a weighting means, to give a respective weight or gain to the current flowing out from at least one of the third signal lines or a digital/analog signal derived from the same.

6. The TCAM device according to claim 2, wherein the searching voltages comprise a plurality of first searching voltages and a plurality of second searching voltages, the first searching voltages are greater than the second searching voltages, and the first searching voltage are different or partly the same.

7. An operation method of a ternary content addressable (TCAM) device, comprising:
by a first driving circuit of the TCAM device, applying a select voltage on one of a plurality of first signal lines, and applying a pass voltage on the rest of the first signal lines, wherein the TCAM device comprises an in-memory searching (IMS) array, the IMS array comprises a plurality of memory units, the plurality of memory units are arranged as a plurality of rows and a plurality of columns, a plurality of control terminal of each row of the memory units are coupled to the first driving circuit via a first signal line, each column of the memory units are serially connected to form a memory unit string, each of the memory unit string is coupled to a second driving circuit via a second signal line; and
by the second driving circuit, applying a plurality of searching voltage corresponding to a target data to the second signal lines.

8. The operation method according to claim 7, wherein the searching voltages comprise a plurality of first searching voltages and a plurality of second searching voltages, the first searching voltages are greater than the second searching voltages, and the first searching voltages are different or partly the same.

9. The operation method according to claim 7, further comprising:
by a sensing circuit coupled to the memory unit strings via a plurality of third signal lines, collecting and adding up currents flowing out from the third signal lines to obtain a total current, wherein a result of comparing the total current with a predetermined threshold represents whether data stored in the memory cells, being coupled to the first signal lines which are applied with the select voltage, match the target data.

10. The operation method according to claim 7, further comprising:
by a sensing circuit coupled to the memory unit strings via a plurality of third signal lines, determining a total value according to a quantity of the third signal lines with current flowing out, wherein a result of comparing the total value with a predetermined threshold represents whether the data stored in the memory cells on the first signal line applied the select voltage matches the target data.

11. A ternary content addressable memory (TCAM) device, comprising:
a first driving circuit;
a second driving circuit;
a sensing circuit; and
an in-memory searching (IMS) array, comprising a first memory unit and a second memory unit, and the first memory unit and the second memory unit are configured as a memory cell,
wherein the first memory unit and the second memory unit are configured on the same row, a control terminal of the first memory unit and a control terminal of the second memory unit are coupled to the first driving circuit via a first signal line, the first memory unit and the second memory unit are configured on two different column, a first terminal of the first memory unit is directly or indirectly coupled to the second driving circuit via a second signal line, a second terminal of the first memory unit is directly or indirectly coupled to the sensing circuit via a third signal line, a first terminal of the second memory unit is directly or indirectly coupled to the second driving circuit via another second signal line, and a second terminal of the second memory unit is directly or indirectly coupled to the sensing circuit via another third signal line, wherein the third signal line and the another third signal line are respectively coupled to the sensing circuit.

12. The TCAM device according to claim 11, wherein while the memory cell is configured to store a first value, the first memory unit is programmed as a high threshold voltage, and the second memory unit is programmed as a low threshold voltage; while the memory cell is configured to store a second value, the first memory unit is programmed as the low threshold voltage, and the second memory unit is programmed as the high threshold voltage; and while the memory cell is configured to store a don't care, the first memory unit is programmed as the high threshold voltage, and the second memory unit is programmed as the high threshold voltage.

13. The TCAM device according to claim 12, wherein while the first memory unit is programmed as the low threshold voltage, and the second memory unit is programmed as the low threshold voltage, the memory cell stores invalid data.
